(19) United States
(12) Patent Application Publication
(10) Pub. No.: US 2009/0101925 A1
(43) Pub. Date: Apr. 23, 2009

(54) Light Emitting Element and Method for Manufacturing the Same

(75) Inventor: Yukio Shakuda, Kyoto (JP)

Correspondence Address: RABIN & Berdo, PC, 1101 14TH STREET, NW, SUITE 500, WASHINGTON, DC, 20005, US

(73) Assignee: Rohm Co., LTD., Kyoto-fu (JP)

(21) Appl. No.: 12/224,558

(22) PCT Filed: Mar. 1, 2007
(86) PCT No.: PCT/JP2007/053910

§ 371 Date: Aug. 29, 2008

(30) Foreign Application Priority Data
Mar. 1, 2006 (JP) 2006-055453

(51) Int. Cl. H01L 33/00; H01L 21/02

(52) U.S. Cl. 257/94; 438/46; 257/E33.003; 257/E21.002

(57) ABSTRACT

A light emitting element including: a growth substrate, which has, as a main plane, a plane on which cleavage directions are orthogonal to each other; a first nitride semiconductor layer formed on the main plane of the growth substrate; an active layer formed on the first nitride semiconductor layer; and a second nitride semiconductor layer formed on the active layer. An angle formed on the main plane by the side of the growth substrate and one of the cleavage directions is ranging approximately from 30° to 60°.

### TECHNICAL FIELD

The present invention relates to a light emitting element which includes an active layer between a first nitride semiconductor layer and a second nitride semiconductor layer, and a method for manufacturing the light emitting element.

### BACKGROUND ART

Heretofore, there has been widely known a light emitting element having a nitride semiconductor formed on a growth substrate (for example, a sapphire substrate) which has, as a main plane, a C-plane having a (0001) plane direction.

Meanwhile, when the light emitting element having the nitride semiconductor formed on the C-plane of the sapphire substrate is a light emitting diode (LED), an influence is occurred in which an emission wavelength of the LED is shortened, when a current is increased from a minute current.

Therefore, in order to suppress the influence that the emission wavelength of the LED is shortened, studies have been conducted on an LED having a nitride semiconductor formed on a sapphire substrate which has, as a main plane, an R-plane having a (1-102) plane direction or an M-plane having a (1-100) plane direction (for example, Japanese Patent Application Publication No. H8-64912 (claim 1, [0030] and the like)).

Moreover, when a sapphire substrate having a plurality of LED chips formed on the sapphire substrate is cut into each of the plurality of LED, the sapphire substrate is cut into LED chips along cleavage directions of an R-plane or an M-plane, from the viewpoint of easiness of processing.

Note that the cleavage directions of the R-plane or the M-plane indicate directions in which the sapphire substrate can easily break, and extending directions of boundaries between crystals of the sapphire substrate on the R-plane or on the M-plane.

### DISCLOSURE OF THE INVENTION

However, the R-plane and the M-plane described above have cleavage directions orthogonal to each other. Therefore, when the sapphire substrate is cut along one of the cleavage directions, the other cleavage direction is set to be a direction orthogonal to a cut surface formed along one of the cleavage directions.

Here, when a dislocation occurs in the cut surface formed along one of the cleavage directions, the dislocation is grown along the other cleavage direction while allowing a current to continue to flow through the light emitting element. Specifically, the dislocation is likely to be grown toward a center portion of the LED. Thus, life of the light emitting element may be shortened.

A first aspect of the present invention is summarized as a light emitting element, including: a growth substrate (a sapphire substrate 10) having, as a main plane, a plane on which cleavage directions are orthogonal to each other; a first nitride semiconductor layer (buffer layer 20 and an n-type cladding layer 30) formed on the main plane of the growth substrate; an active layer (an MQW active layer 40) formed on the first nitride semiconductor layer; and a second nitride semiconductor layer (a p-type cladding layer 50 and a p-type contact layer 60) formed on the active layer, wherein an angle formed on the main plane by a side of the growth substrate (a cutting direction u₁) and one of the cleavage directions (a cleavage direction t₁) is ranging approximately from 30° to 60°.

According to this aspect, the angle formed by the cleavage direction t₁ and the cutting direction u₁ is ranging approximately from 30° to 60°. Accordingly, the cleavage direction orthogonal to the other cleavage direction is not orthogonal to a side of the growth substrate on the main plane.

Thus, even when a dislocation occurs in the cut surface formed along the side of the growth substrate of the main surface, it is possible to reduce the possibility that the dislocation is grown toward the center portion of the light emitting element while allowing the current to continue to flow through the light emitting element. Further, the life of the light emitting element can be extended.

A second aspect of the present invention is summarized in that, in the first aspect of the invention, the main plane is any one of an R-plane having a (1-102) plane direction and an M-plane having a (1-100) plane direction.

A third aspect of the present invention is summarized in that, in the first aspect of the invention, the growth substrate is any one of a sapphire substrate, a GaN substrate and an SiC substrate.

A fourth aspect of the present invention is summarized as a method for manufacturing a light emitting element which includes an active layer between a first nitride semiconductor layer and a second nitride semiconductor layer, including: forming the first nitride semiconductor layer on a main plane of a growth substrate which has, as the main plane, a plane on which cleavage directions are orthogonal to each other; forming the active layer on the first nitride semiconductor layer; forming the second nitride semiconductor layer on the active layer; and cutting the growth substrate and the first nitride semiconductor layer into each of the light emitting element, wherein an angle formed by a direction for cutting the growth substrate and the first nitride semiconductor layer, and one of the cleavage directions, is ranging approximately from 30° to 60°.

A fifth aspect of the present invention is summarized in that, in the fourth aspect of the invention, the main plane is any one of an R-plane having a (1-102) plane direction and an M-plane having a (1-100) plane direction.

A sixth aspect of the present invention is summarized in that, in the fourth aspect of the invention, the growth substrate is any one of a sapphire substrate, a GaN substrate and a SiC substrate.

### BRIEF DESCRIPTION OF THE DRAWINGS

FIG. 1 is a view showing a light emitting element array 100 according to an embodiment of the present invention.

FIG. 2 is a cross-sectional view showing the light emitting element array 100 according to the embodiment of the present invention.

FIG. 3 is a view showing plane directions of a sapphire substrate 10 according to the embodiment of the present invention.

FIG. 4 is a view showing an example of cleavage directions of a main plane of the sapphire substrate 10 according to the embodiment of the present invention.

FIG. 5 is a flowchart showing a method for manufacturing a light emitting element 200 according to the embodiment of the present invention.

FIG. 6 is a view showing a light emitting element array 100 according to an example of the present invention.

FIG. 7 is a view showing a light emitting element 200 according to the example of the present invention.

### BEST MODES FOR CARRYING OUT THE INVENTION

With reference to the accompanying drawings, embodiments of the present invention will be described below. Note that, in the following description of the drawings, the same or similar parts will be denoted by the same or similar reference numerals. It should be noted that the drawings are conceptual.

### (Configuration of Light Emitting Element Array)

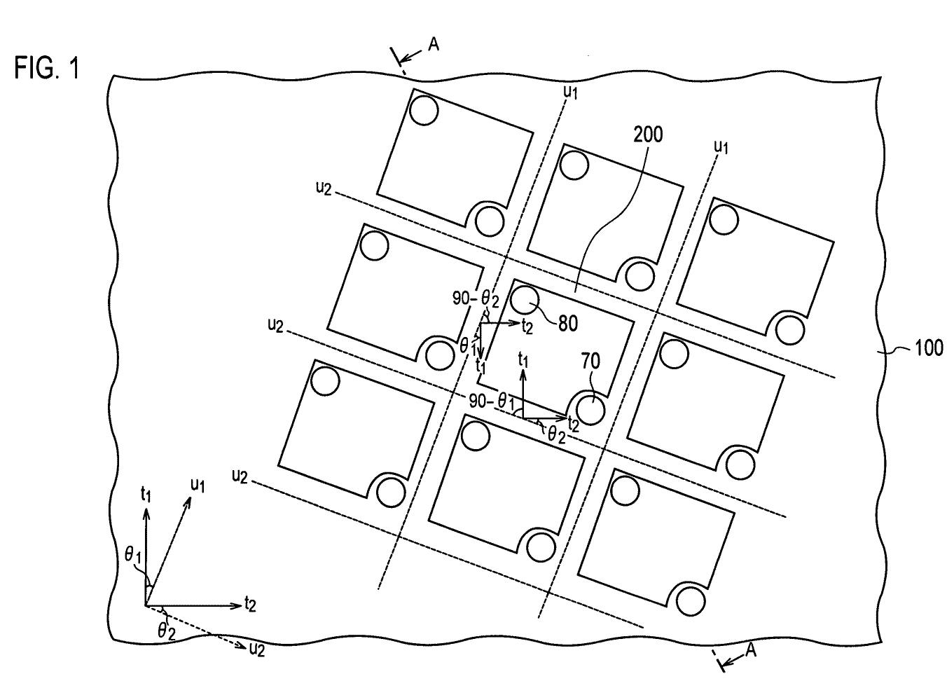

With reference to the accompanying drawings, a light emitting element array according to an embodiment of the present invention will be described below. FIG. 1 is a view showing a light emitting element array 100 according to the embodiment of the present invention.

As shown in FIG. 1, a plurality of light emitting elements 200 are arranged in the light emitting element array 100. Moreover, each of the light emitting elements 200 is cut out when the light emitting element array 100 is cut along cutting directions u₁ and u₂.

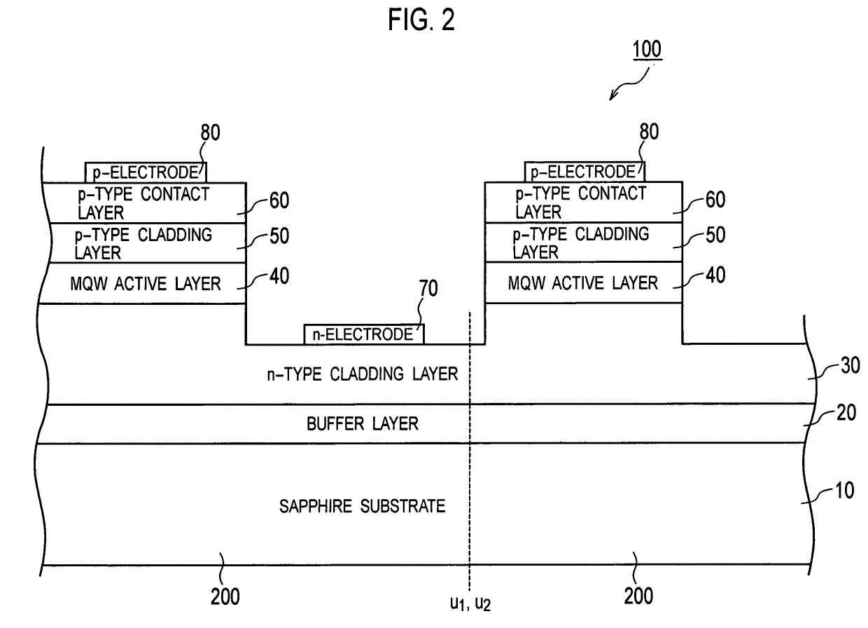

As described later, the light emitting element array 100 has a structure in which a sapphire substrate 10, a buffer layer 20, an n-type cladding layer 30, an MQW active layer 40, a p-type cladding layer 50 and a p-type contact layer 60 are sequentially laminated. Further, an n-electrode 70 is formed on the n-type cladding layer 30. Moreover, a p-electrode 80 is formed on the p-type contact layer 60 (see FIG. 2).

Here, examples of the light emitting element 200 include a light emitting diode (LED), a semiconductor laser, an element formed by combining a light emitting diode or a semiconductor laser with a fluorescent material, and the like. The light emitting element 200 may also be an electronic device such as a HEMT (High Electron Mobility Transistor) including a nitride semiconductor layer, a SAW (Surface Acoustic Wave) device, a light receiving element or the like.

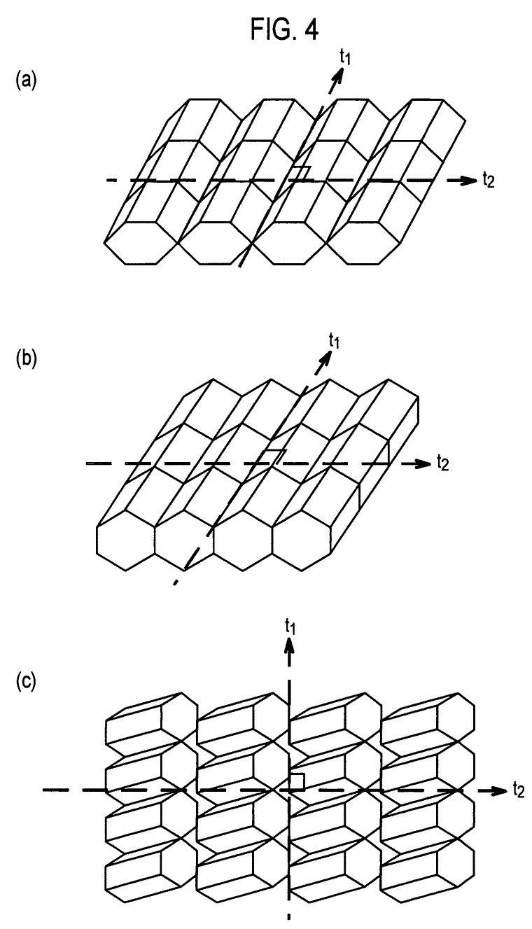

The sapphire substrate 10 includes, as a main plane, a plane on which cleavage directions (a cleavage direction t₁ and a cleavage direction t₂) are orthogonal to each other. Each nitride semiconductor layers is laminated on the main plane of the sapphire substrate 10. Note that the cleavage directions indicates directions in which the sapphire substrate 10 can easily break and are extending directions of boundaries between crystals on the main plane of the sapphire substrate 10. Note that detailed descriptions concerning the cleavage directions will be given later (see FIG. 4).

Note that examples of the plane which have the cleavage directions t₁ and t₂ orthogonal to each other include an M-plane having a (1-100) plane direction, an A-plane having a (11-20) plane direction, an R-plane having a (1-102) plane direction and the like.

Here, an angle θ₁ formed by the cutting direction u₁ and the cleavage direction t₁ is ranging approximately from 30° to 60°. Similarly, an angle θ₂ formed by the cutting direction u₂ and the cleavage direction t₂ is approximately ranging from 30° to 60°.

Moreover, assuming that a dislocation occurs in a cut surface formed along the side of the sapphire substrate 10 (the side extended in the cutting direction u₁ or the cutting direction u₂) on the main plane, a direction in which the dislocation is likely to be grown is the cleavage direction t₁ or the cleavage direction t₂.

To be more specific, on the sapphire substrate 10, when a dislocation occurs in the cut surface formed along the side extending in the cutting direction u₁, the dislocation is likely to be grown in the cleavage direction t₁ (a direction tilted at θ₁ to the cutting direction u₁) or in the cleavage direction t₂ (a direction tilted at 90-θ₂ to the cutting direction u₁). Similarly, on the sapphire substrate 10, when a dislocation occurs in the cut surface formed along the side extending in the cutting direction u₂, the dislocation is likely to be grown in the cleavage direction t₁ (a direction tilted at 90-θ₁ to the cutting direction u₂) or in the cleavage direction t₂ (a direction tilted at θ₂ to the cutting direction u₂).

With reference to the accompanying drawings, description will be given below of a cross-section of the above-described light emitting element array 100. FIG. 2 is a cross-sectional view showing the light emitting element array 100 as seen from the direction A as shown in FIG. 1.

As shown in FIG. 2, the light emitting element array 100 has the structure in which the sapphire substrate 10, the buffer layer 20, the n-type cladding layer 30, the MQW active layer 40, the p-type cladding layer 50 and the p-type contact layer 60 are sequentially laminated. Moreover, the n-electrode 70 is formed on the n-type cladding layer 30 and the p-electrode 80 is formed on the p-type contact layer 60.

The sapphire substrate 10 is a growth substrate formed of a single crystal sapphire. The sapphire substrate has, as the main plane, the plane on which the cleavage directions t₁ and t₂ are orthogonal to each other, as described above.

The buffer layer 20 is formed of GaN or the like. The buffer layer 20 includes a function of reducing a lattice constant mismatch between the n-type cladding layer 30 and the MQW active layer 40.

The n-type cladding layer 30 is a layer formed of a material (for example, GaN) which has a band gap energy larger than that of the MQW active layer 40. The n-type cladding layer 30 includes a function of confining carriers in the MQW active layer 40.

The MQW active layer 40 has a structure in which well layers and barrier layers are alternately laminated. Each of the well layers is a thin film layer (for example, InGaN) having an In composition ratio larger than that of each of the barrier layers. On the other hand, each of the barrier layer is a thin film layer (for example, GaN) having the In composition ratio smaller than that of each of the well layer. Moreover, the well layers and the barrier layers form a multiple quantum well structure (MQW structure).

The p-type cladding layer 50 is a layer formed of a material (for example, GaN) which has a band gap energy larger than that of the MQW active layer 40. The 9-type cladding layer 50 includes a function of confining carriers in the MQW active layer 40.

The p-type contact layer 60 is a layer containing impurities such as Mg. The p-type contact layer 60 includes a function of preventing occurrence of a schottky barrier.

### (Plane Directions of Sapphire Substrate)

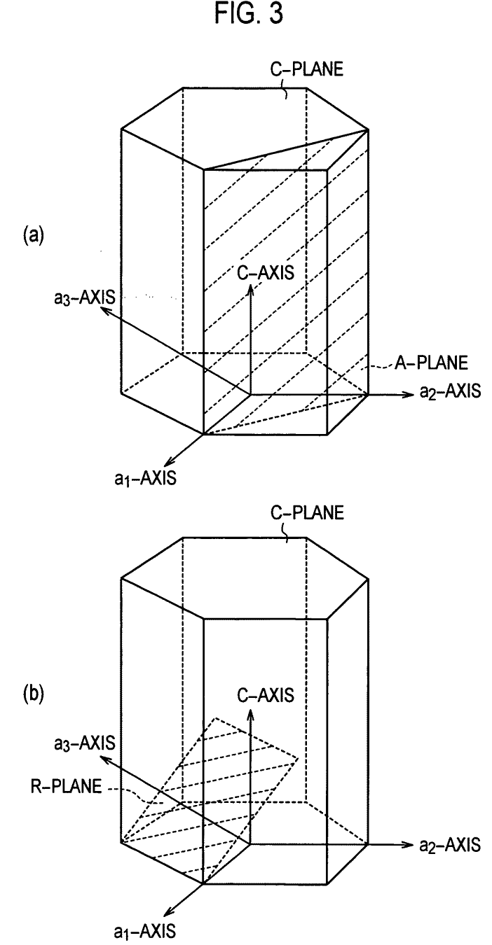

With reference to the accompanying drawings, description will be given below of plane directions of the sapphire substrate according to the embodiment of the present invention. FIGS. 3 (a) and 3 (b) are views showing plane directions of the sapphire substrate 10 according to the embodiment of the present invention.

The plane directions of the sapphire substrate 10 are represented by coordinates on axes a₁, a₂, a₃ and c. Specifically, when coordinates of points at which a target plane and the respective axes intersect each other are indicated as a₁, a₂, a₃ and c₁ respectively, a plane direction of the target plane is represented as (1/a₁, 1/a₂, 1/a₃, 1/c).

Therefore, as shown in FIG. 3 (a), a plane direction of an A-plane of the sapphire substrate 10 is represented as (11-20), and a plane direction of an M-plane of the sapphire substrate 10 is represented as (1-100). Similarly, as shown in FIG. 3 (b), a plane direction of an R-plane of the sapphire substrate 10 is represented as (1-102).

### (Cleavage Directions of Main Plane)

With reference to the accompanying drawings, description will be given below of cleavage directions of the main plane of the growth substrate according to the embodiment of the present invention. FIGS. 4 (a) to 4 (c) are views showing examples of the cleavage directions of the main plane of the sapphire substrate 10 according to the embodiment of the present invention.

FIG. 4 (a) is a perspective view showing cleavage directions of the M-plane as the main plane of the sapphire substrate 10. As shown in FIG. 4 (a), when the M-plane of the sapphire substrate 10 is the main plane, the cleavage directions of the sapphire substrate 10, or directions in which the sapphire substrate 10 easily breaks, indicate extending directions of boundaries between crystals on the M-plane. In other words, the cleavage directions of the sapphire substrate 10 indicate two directions (the cleavage directions t₁ and t₂) orthogonal to each other.

FIG. 4 (b) is a perspective view showing cleavage directions of the A-plane as the main plane of the sapphire substrate 10. As shown in FIG. 4 (b), when the A-plane of the sapphire substrate 10 is the main plane, the cleavage directions of the sapphire substrate 10, or directions in which the sapphire substrate 10 easily breaks, indicate extending directions of boundaries between crystals on the A-plane. In other words, the cleavage directions of the sapphire substrate 10 indicate two directions (the cleavage directions t₁ and t₂) orthogonal to each other.

FIG. 4 (c) is a perspective view showing cleavage directions of the R-plane as the main plane of the sapphire substrate 10. As shown in FIG. 4 (c), when the R-plane of the sapphire substrate 10 is the main plane, the cleavage directions of the sapphire substrate 10, or directions in which the sapphire substrate 10 easily breaks, indicate extending directions of boundaries between crystals on the R-plane. In other words, the cleavage directions of the sapphire substrate 10 indicate two directions (the cleavage directions t₁ and t₂) orthogonal to each other.

### (Method for Manufacturing Light Emitting Element)

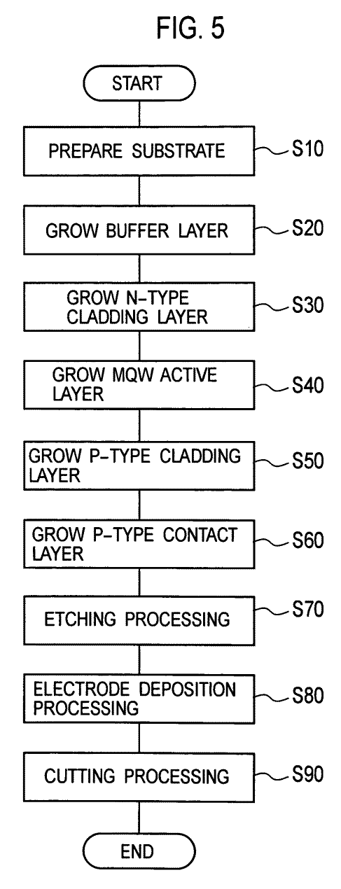

With reference to the accompanying drawing, description will be given below of a method for manufacturing a light emitting element according to the embodiment of the present invention. With reference to FIG. 5, description will be given of a method for manufacturing the light emitting element 200 according to the embodiment of the present invention.

As shown in FIG. 5, in Step S10, a sapphire substrate 10 is prepared. Then, hydrogen (H₂) is supplied into a gas chamber so as to clean the sapphire substrate 10.

In Step S20, a buffer layer 20 is formed on the sapphire substrate 10. Specifically, a temperature of the sapphire substrate 10 is lowered to about 500° C. At the same time, nitrogen (N₂), trimethylgallium (TMG) and the like are supplied into the gas chamber to form the buffer layer 20 by a vapor phase growth of a solid crystal.

Note that examples of a method for growing the solid crystal in the vapor phase include a MOCVD (Metal Organic Chemical Vapour Deposition) method and the like.

In Step S30, an n-type cladding layer 30 is formed on the buffer layer 20. Specifically, the temperature of the sapphire substrate 10 is increased to about 1060° C. At the same time, ammonia (NH₃), hydrogen (H₂), nitrogen (N₂), trimethylgallium (TMG), monosilane (SiH₄) and the like are supplied into the gas chamber to form the n-type cladding layer 30 by a vapor phase growth of a solid crystal.

In Step S40, an MQW active layer 40 is formed on the n-type cladding layer 30. Specifically, the temperature of the sapphire substrate 10 is increased to about 1060° C. At the same time, ammonia (NH₃), hydrogen (H₂), nitrogen (N₂), trimethylgallium (TMG) and the like are supplied into the gas chamber to form a barrier layer, by a vapor phase growth of a solid crystal. Further, the temperature of the sapphire substrate 10 is lowered to about 760° C. At the same time, ammonia (NH₃), nitrogen (N₂), triethylgallium (TEG), trimethylindium (TMI), monosilane (SiH₄) and the like are supplied into the gas chamber to form a well layer by a vapor phase growth of a solid crystal. As described above, by alternately laminating the barrier layers and the well layers, the MQW active layer 40 having a multiple quantum well structure (MQW structure) is formed.

In Step S50, a p-type cladding layer 50 is formed on the MQW active layer 40. Specifically, as shown in FIG. 3, the temperature of the sapphire substrate 10 is increased to about 1060° C. At the same time, ammonia (NH₃), hydrogen (H₂), nitrogen (N₂), trimethylgallium (TMG), trimethylaluminum (TMA) and the like are supplied into the gas chamber to form the p-type cladding layer 50 by a vapor phase growth of a solid crystal.

In Step S60, a p-type contact layer 60 is formed on the p-type cladding layer 50. Specifically, source gas containing impurities such as Mg is supplied into the gas chamber to form the p-type contact layer 60 by a vapor phase growth of a solid crystal.

In Step S70, an etching is partially performed on the n-type cladding layer 30, the MQW active layer 40, the p-type cladding layer 50 and the p-type contact layer 60. Thus, the n-type cladding layer 30 is exposed

In Step S80, an n-electrode 70 is deposited on a surface of the n-type cladding layer 30, and a p-electrode 80 is deposited on a surface of the p-type contact layer 60. The n-electrode 70 and the p-electrode 80 are deposited on the surfaces of the n-type cladding layer 30 and the p-type contact layer 60, respectively, by use of, for example, a vacuum deposition method or the like.

Thus, by the processing in Step S10 to Step S80, a light emitting element array 100 having a plurality of light emitting elements 200 arranged therein is formed.

In Step S90, each of the light emitting elements 200 is cut out by cutting the light emitting element array 100. Specifically, each of the light emitting elements 200 is cut out when the light emitting element array 100 is cut along cutting directions u₁ and u₂.

Note that, as described above, the angle θ₁, which is formed on the main plane of the sapphire substrate 10 by the cleavage direction t₁ and the cutting direction u₁, is ranging approximately from 30° to 60°. Similarly, the angle θ₂, which is formed on the main plane of the sapphire substrate 10 by the cleavage direction t₂ and the cutting direction u₂, is ranging approximately from 30° to 60°.

In addition, examples of a method for cutting the light emitting element array 100 include a method for dicing the array by use of a blade, a method for breaking the array by applying impact thereto after scratching the array along the cutting directions, a method for breaking the array after forming grooves along the cutting directions by use of a laser, and the like.

### (Operations and Effects)

According to the light emitting element 200 and the method for manufacturing the light emitting element 200 according to the embodiment of the present invention, the angle θ₁ formed on the main plane of the sapphire substrate 10 by the cleavage direction t₁ and the cutting direction u₁ (that is, the side of the sapphire substrate 10 on the main plane) is ranging approximately from 30° to 60°.

Therefore, even when a dislocation occurs in the sapphire substrate 10, it is possible to reduce a possibility that the dislocation is grown toward the center portion of the light emitting element 200 while allowing the current to continue to flow through the light emitting element 200.

To be more specific, as in the case of the conventional technology, when the cleavage direction t₁ and the cutting direction u₁ are parallel to each other, the cleavage direction t₂ orthogonal to the cleavage direction t₁ is orthogonal to the cutting direction u₁ (that is, the side of the sapphire substrate 10 on the main plane). Thus, the dislocation is likely to be grown toward the center portion of the light emitting element 200.

On the other hand, as in the case of the embodiment of the present invention, when the angle formed by the cleavage direction t₁ and the cutting direction u₁ is ranging approximately from 30° to 60°, the cleavage direction t₂ orthogonal to the cleavage direction t₁ is not orthogonal to the cutting direction u₁ (that is, the side of the sapphire substrate 10 on the main plane). Thus, it is possible to reduce the possibility that the dislocation is grown toward the center portion of the light emitting element 200.

In the same manner, as in the case of the embodiment of the present invention, when the angle formed by the cleavage direction t₂ and the cutting direction u₂ is ranging approximately from 30° to 60°, the cleavage direction t₁ orthogonal to the cleavage direction t₂ is not orthogonal to the cutting direction u₂ (that is, the side of the sapphire substrate 10 on the main plane). Thus, it is possible to reduce the possibility that the dislocation is grown toward the center portion of the light emitting element 200.

As described above, the possibility that the dislocation is grown toward the center portion of the light emitting element 200 is reduced. Accordingly, life of the light emitting element 200 can be extended.

### OTHER EMBODIMENTS

The present invention has been described based on the embodiment described above. However, it should be understood that the present invention is not limited to the description and drawings which constitute a part of this disclosure. From this disclosure, various alternative embodiments, examples and operational technologies will become apparent to those skilled in the art.

For example, in the above embodiment, the description has been given for the example in which the nitride semiconductor layer is formed by a crystal grown by use of the MOCVD method. However, the present invention is not limited to this method. The nitride semiconductor layer may be formed by the crystal grown by use of a HVPE method, a gas source MBE method or the like. Moreover, a crystal structure of the nitride semiconductor may be a wurtzite structure or a zinc blend structure.

Moreover, in the above embodiment, the description has been given for the example in which the nitride semiconductor layer is a layer made of GaN, AlGaN, InGaN or the like. However, the present invention is not limited to those, and the nitride semiconductor layer may be one having a composition other than GaN, AlGaN and InGaN.

Furthermore, in the above embodiment, the sapphire substrate is used as the substrate for forming the nitride semiconductor layer. However, the present invention is not limited to a sapphire substrate, and a substrate capable of forming the nitride semiconductor layer by the crystal growth, for example, one made of Si, SiC, GaAs, MgO, ZnO, spinel, GaN or the like may be used.

Moreover, in the above embodiment, the n-type nitride semiconductor layer, the superlattice layer, the active layer and the p-type semiconductor layer are sequentially laminated on the sapphire substrate. However, the present invention is not limited to this configuration. The p-type nitride semiconductor layer, the active layer, the superlattice layer and the n-type semiconductor layer may be sequentially laminated on the sapphire substrate.

As described above, the present invention includes various embodiments and the like which are not described herein, as a matter of course. Thus, the technical scope of the present invention is defined only by claimed elements of the invention according to the appropriate scope of the claims on the basis of the descriptions above.

### EXAMPLE

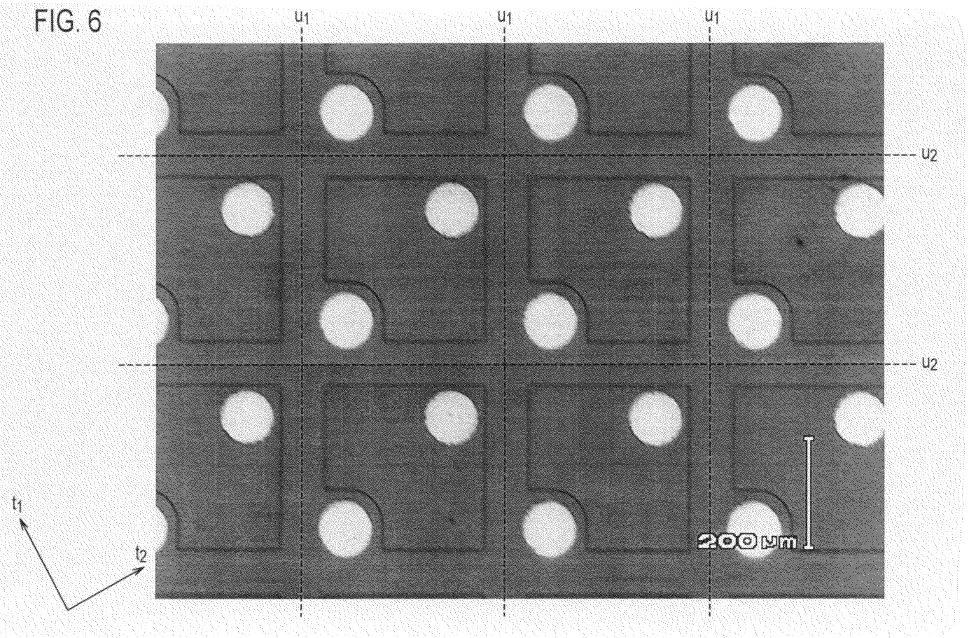

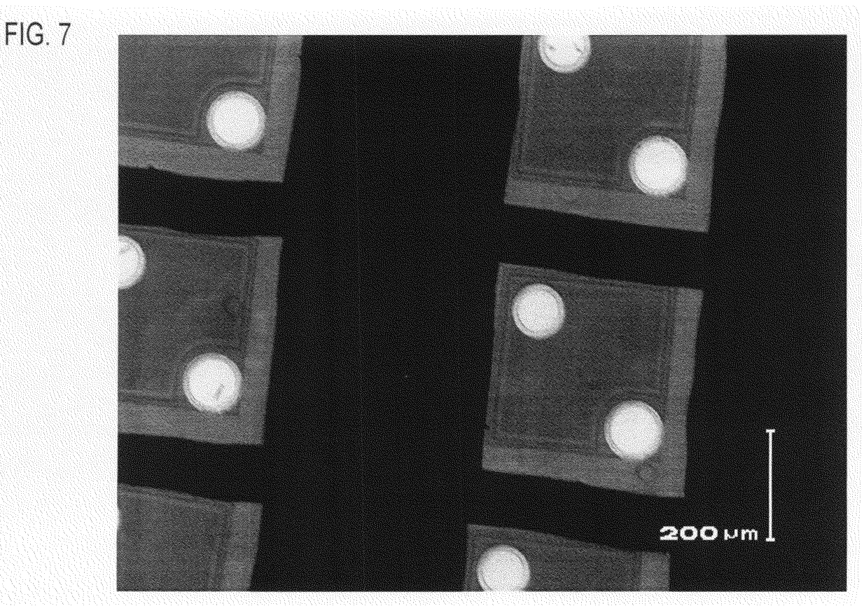

With reference to the accompanying drawings, description will be given below of a light emitting element array 100 and a light emitting element 200 according to an example of the present invention. FIG. 6 is a view showing the light emitting element array 100 according to the example of the present invention. FIG. 7 is a view showing the light emitting element 200 according to the example of the present invention.

First, each nitride semiconductor layers was laminated on a main plane of a sapphire substrate 10 which had, as the main plane, a plane on which cleavage directions t₁ and t₂ were orthogonal to each other. Thus, the light emitting element array 100 shown in FIG. 6 was formed.

Next, the light emitting element array 100 was cut along a cutting direction u₁ tilted at θ₁ (30°≦θ₁≦60°) to the cleavage direction t₁, and the light emitting element array 100 was cut along a cutting direction u₂ tilted at θ₂ (30°≦θ₂≦60°) to the cleavage direction t₂. Thus, the light emitting element 200 shown in FIG. 7 was cut out from the light emitting element array 100.

As shown in FIG. 7, it was confirmed that the side of the light emitting element 200 on the main plane (the side extended in the cutting direction u₁ or in the cutting direction u₂) was not set to have a clear straight line, since the light emitting element array 100 was not cut along the cleavage direction t₁ or the cleavage direction t₂.

Meanwhile, it was also confirmed that any adverse effect was given for the MQW active layer 40 laminated on the sapphire substrate 10, although the side of the light emitting element 200 was not set to have the clear straight line.

Further, the angle formed by the cleavage direction t₁ and the cutting direction u₁ was θ₁ (30°≦θ₁≦60°) and the angle formed by the cleavage direction t₂ and the cutting direction u₂ was θ₂ (30°≦θ₂≦60°). Therefore, even when a dislocation occurs in the side of the light emitting element 200 when the light emitting element array 100 is cut, a possibility that the dislocation is grown toward a center portion of the light emitting element 200 may be reduced.

### INDUSTRIAL APPLICABILITY

The present invention can provide a light emitting element and a method for manufacturing the light emitting element, which make it possible to extend life of the light emitting element by reducing a possibility that a dislocation is grown toward a center portion of the light emitting element while allowing a current to continue to flow through the light emitting element.

1. A light emitting element, comprising:
a growth substrate having, as a main plane, a plane on which cleavage directions are orthogonal to each other;
a first nitride semiconductor layer formed on the main plane of the growth substrate;
an active layer formed on the first nitride semiconductor layer; and
a second nitride semiconductor layer formed on the active layer,
wherein an angle formed on the main plane by a side of the growth substrate and one of the cleavage directions is ranging approximately from 30° to 60°.

2. The light emitting element according to claim 1, wherein
the main plane is any one of an R-plane having a (1-102) plane direction and an M-plane having a (1-100) plane direction.

3. The light emitting element according to claim 1, wherein
the growth substrate is any one of a sapphire substrate, a GaN substrate and an SiC substrate.

4. A method for manufacturing a light emitting element which includes an active layer between a first nitride semiconductor layer and a second nitride semiconductor layer, comprising:
growing the first nitride semiconductor layer on a main plane of a growth substrate which has, as the main plane, a plane on which cleavage directions are orthogonal to each other;
growing the active layer on the first nitride semiconductor layer;
growing the second nitride semiconductor layer on the active layer; and
cutting the growth substrate and the first nitride semiconductor layer into each of the light emitting element,
wherein an angle formed by a direction for cutting the growth substrate and the first nitride semiconductor layer, and one of the cleavage directions, is ranging approximately from 30° to 60°.

5. The method for manufacturing the light emitting element according to claim 4, wherein
the main plane is any one of an R-plane having a (1-102) plane direction and an M-plane having a (1-100) plane direction.

6. The method for manufacturing the light emitting element according to claim 4, wherein
the growth substrate is any one of a sapphire substrate, a GaN substrate and a SiC substrate.
